(19) United States
(12) Patent Application Publication
(10) Pub. No.: US 2010/0067714 A1
(43) Pub. Date: Mar. 18, 2010

(54) HEADPHONES SWITCHABLE TO A SOUND BOX MODE OF OPERATION

(76) Inventor: Kuo-Shu CHENG, Hsin-Dian City (TW)

Correspondence Address: Muncy, Geissler, Olds & Lowe, PLLC, P.O. BOX 1364, FAIRFAX, VA, 22038-1364, US

(21) Appl. No.: 12/557,189

(22) Filed: Sep. 10, 2009

(30) Foreign Application Priority Data
Sep. 16, 2008 (TW) 097135443
Dec. 19, 2008 (TW) 097149673

(51) Int. Cl. H04R 1/10; H03G 3/00

(52) U.S. Cl. 381/74; 381/109

(57) ABSTRACT

A set of headphones switchable to a sound box mode of operation comprises two ear shells each of which has a speaker. An inner chamber of each ear shell is configured with a transmission line of Helmholtz resonance. A vent aperture of the transmission line is located on an outer case of each ear shell. A cord having a connector plug is connected with the speakers in the ear shells. A portion of the cord is also provided with an audio power amplifier connected between the connector plug and the speakers. A switch is also provided, operable to switch an audio signal outputted to the speakers between different levels of power.

### BACKGROUND OF THE INVENTION

1. Field of the Invention

The present invention generally relates to headphones, and more particularly to headphones switchable to a sound box mode of operation.

2. The Prior Arts

Headphones and sound boxes generally include speakers for emitting sound based on audio signals. The headphones are typically small in volume, have small power and are able to emit only a small sound volume. In use, the headphones thus have to be placed close to the user's ears. In contrast, the sound box has a larger volume, has higher power and is able to emit a higher and more vivid sound volume.

Practically, it is frequent that a user listening to an audio record wishes to switch between headphones and sound box to experience the audio record in desirable conditions. For this purpose, a headphones/sound box converter device is currently commercialized on the market. During operation, the respective plugs of the headphones and sound box are connected with the converter device, which is provided with a switch operable to switch the audio output between the headphones and sound box. However, this type of converter device requires the presence of the headphones and sound box at the same time, which may not be suitable for every configuration of use.

Chinese Patent Application Nos. 200620137507.2 and 200620157870.0 disclose headphones that have sound box capabilities. However, the headphones described in these patents require two sets of speakers, one set of speakers specifically configured for a regular headphone mode of operation, and another set of speakers specifically configured for a sound box mode of operation. As a result, the headphones become heavy and uncomfortable in use.

### SUMMARY OF THE INVENTION

In order to overcome the disadvantages of the prior art, the present invention provides a set of headphones that is able to switch between a regular headphone mode and sound box mode of operation for outputting sound through a single set of speakers.

According to one embodiment of the present invention, the set of headphones comprises two ear shells each of which is internally provided with a speaker and has an inner chamber configured with a transmission line of Helmholtz resonance, an open hole located at an outer case of each ear shell is used as a vent aperture of the transmission line, a cord having a connector plug, wherein the cord is connected with the speakers, and a portion of the cord is provided with an audio power amplifier connected between the connector plug and the speakers, and a switch operable to switch an audio signal outputted through the speakers between different levels of power.

The connector plug may be a RCA audio plug as provided on conventional headphones. When the audio output equipment includes a USB interface provided with audio output capabilities (such as a computer host), the connector plug may also be a USB plug, and the headphones may further comprise an USB-audio signal converter interface coupled in series on the cord between the USB plug and the audio power amplifier. In a sound box mode of operation, the digital audio signal produced by an audio output equipment is transmitted through the USB connector plug to the USB-audio signal converter interface. The USB-audio signal converter interface then converts the digital audio signal into an analog audio signal. The analog audio signal is then amplified through the audio power amplifier, and outputted to the speakers. As a result, the sound outputted from the speakers has a higher power and can be heard with a higher sound volume. For a regular headphone mode of operation (i.e. lower level of power and lower sound volume at the output of the speakers), the switch may be operated to switch a different audio output power to the speakers. This may be accomplished through different ways, such as by switching an attenuator, setting the amplification magnitude of the audio power amplifier to one, or directly connecting the input of the speakers with the audio output of the USB-audio signal converter interface, etc.

The function of the switch is mainly to provide an audio signal of different output power to the speakers. This function of the switch may be achieved by enabling or disabling the audio power amplifier. The switch may be a sliding switch, push button switch, or a rotary switch with volume control functionality.

In one embodiment, the audio power amplifier, USB-audio signal converter interface, and like electric components for processing audio signals are placed in any one of the ear shells. In other embodiments, the audio power amplifier, USB-audio signal converter interface, and like electric components for processing audio signals may be placed in an enclosing case. Further, the switch may also be provided in the enclosing case. For a flexible use, the enclosing case may include a socket configured as an audio input interface. When an external audio signal source is coupled with the audio input interface, all the connections with the audio output of the USB-audio signal converter interface are switched to the audio input interface. For a level of output power in the sound box mode of operation, the enclosing case may also include a power socket adapted to connect with an external power source for supplying power to the audio power amplifier. The audio power amplifier is thereby able to yield higher levels of output power. The enclosing case may comprise a BASS output connector for connecting with a heavy bass speaker.

In diverse embodiments, the headphones may be implemented for an ear suspension type configuration of use or mounted with a head band. In particular, each ear shell may be mounted to one end of the head band through a rotary or detachable link structure. The ear shells can thereby rotate or be detached from the head band to switch between the headphone and sound box modes of operation. In addition, the head band may also be a foldable or detachable head band, which may be achieved by providing a suitable folding or detachment structure at a proper portion (preferably central region) of the head band. The head band is thereby divided into two portions that are movable relative to each other to place the two ear shells in different positions corresponding to the headphone and sound box modes of operation. To enable automatic switching between the headphone and sound box modes of operation, the switch mechanism may also be connected with either the link structure between each ear shell and the head band, or the folding or detachment structure on the head band.

Furthermore, an inner chamber of each ear shell is configured with a transmission line of Helmholtz resonance. A vent aperture at one end of the transmission line is located on an outer case of the ear shell, which is an open hole on a rear wall of the outer case of the ear shell. The speaker is located on a front end of the out case. The outer case and the speaker define a chamber that has a relatively larger accommodating space. A rear interior of the outer case has a plurality of concentric rings with a center on a central axis of the vent aperture. A concentric annular lid covers the vent aperture and the concentric rings, thereby defining an annular channel that communicates the chamber to the vent aperture to constitute the transmission line of Helmholtz resonance adapted to emphasize bass outputs and minimum standing waves. In alternate embodiments, an inner chamber of each ear shell may be filled with a sound absorbing material to yield enhanced sound quality. In addition, the vent aperture of the transmission line of Helmholtz resonance and the speaker may also be located on a same axis. Moreover, an inner surface of the outer case of the ear shell may be defined as a curved shape. Sound waves produced from the speaker thus can be reflected from the curved surface, and then propagate outward through the transmission line of Helmholtz resonance to yield enhanced sound quality.

Furthermore, an occluding member may also be provided for adjusting the size of the vent aperture such that the bass sound pressure output can be controllably adjusted. In a headphone mode of operation, the occluding member may adjust or close the vent aperture to prevent excessively strong bass sound output that may render the listening experience uncomfortable. In a sound box mode of operation, the occluding member is adjusted to an open position. The occluding member may be a baffle movable relative to the vent aperture under control of an operating member for adjusting, closing or opening the vent aperture. Alternatively, the occluding member may also be a sealing element that may be directly full opened from or closed on the vent aperture.

At least one advantage of the present invention is the ability to provide a lightweight and easy-to-carry headphone structure that can be easily switched between a headphone and sound box mode of operation, and save the user's expense.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view illustrating the structure of Embodiment 1 according to the present invention;

FIGS. 2A and 2B are schematic diagrams illustrating diverse modes of circuit operation of the Embodiment 1;

FIGS. 3A, 3B and 3C are schematic diagrams illustrating diverse configurations of use of the Embodiment 1;

FIGS. 4A, 4B, 4C and 4D are schematic diagrams illustrating diverse configurations of use of Embodiment 2 according to the present invention;

FIG. 5 is a schematic view illustrating the structure of Embodiment 3 according to the present invention;

FIGS. 6A and 6B are schematic diagrams illustrating diverse modes of circuit operation of the Embodiment 3;

FIG. 7 is a schematic view illustrating the structure of Embodiment 4 according to the present invention;

FIG. 8 is a schematic view illustrating the structure of Embodiment 5 according to the present invention;

FIG. 9 is a schematic view illustrating the structure of one ear shell according to an embodiment of the present invention; and

FIG. 10 is a graph comparing sound pressure outputs of headphones according to an embodiment of the present invention and conventional headphones; and

FIG. 11 is a cross-sectional view of a headphone including an occluding member that is able to be adjusted to seal a vent aperture on a rear side of an ear shell of the headphone, according to an embodiment of the present invention; and

FIG. 12 is a schematic view illustrating that the occluding member shown in FIG. 11 is adjusted to make the vent aperture be in an open state, according to an embodiment of the present invention.

### DETAILED DESCRIPTION OF THE PREFERRED EMBODIMENTS

### Embodiment 1

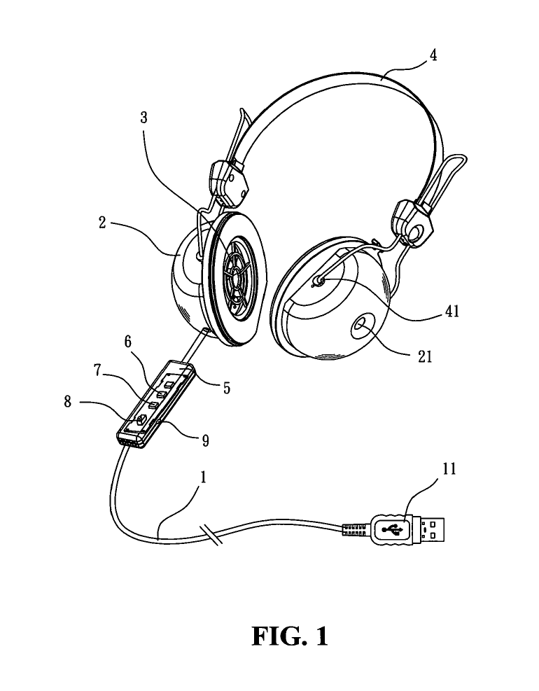

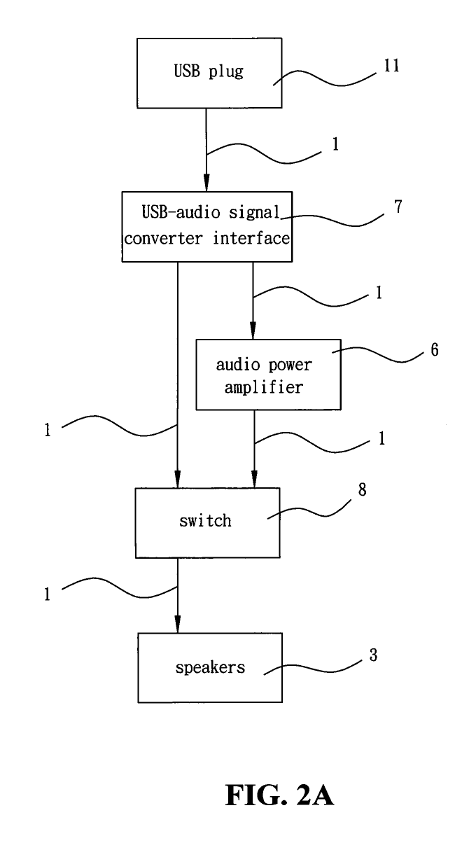

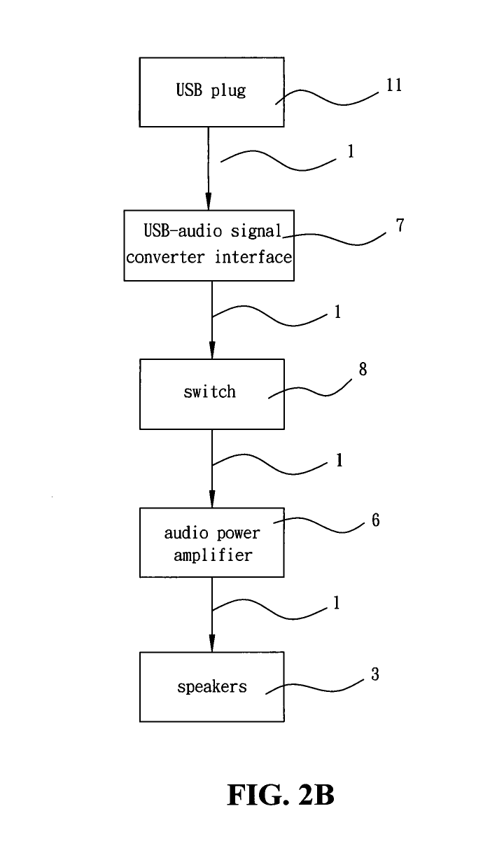

As shown in FIG. 1, a set of headphones according to a first embodiment of the present invention mainly comprises a head band 4, two ear shells 2, and a cord 1 having a connector plug 11. Each ear shell 2 is connected with an end of the head band 4 through a link 41. The interior of each ear shell 2 is mounted with a speaker 3 electrically connected with the cord 1. The connector plug 11 is an USB connector plug. A portion of the cord 1 is also provided with an enclosing case 5 in which are respectively assembled a USB-audio signal converter interface 7, a switch 8, a BASS output connector 9, and an audio power amplifier 6. The USB connector plug, USB-audio signal converter interface 7, switch 8, audio power amplifier 6 and speakers 3 constitute the main circuitry of the present invention that operates according to the principle shown in FIGS. 2A and 2B.

FIG. 2A is a schematic diagram illustrating an operation of the electrical circuit structure according to an embodiment of the present invention. When the switch 8 (the switch may be either a push button or sliding tab switch) is turned to a sound box mode of operation, the digital audio signal produced by an audio output equipment (which must have a USB interface with audio output capabilities) is transmitted through the USB connector plug 11 to the USB-audio signal converter interface 7. A digital-to-analog converter (DAC) inside the USB-audio signal converter interface 7 then converts the digital audio signal into an analog audio signal. The analog audio signal is then amplified through the audio power amplifier 6, and outputted to the speakers 3. As a result, the sound signal outputted from the speakers 3 has a higher power and can be heard with a higher sound volume such as from a sound box. When the switch 8 is turned to a regular headphone mode of operation, the analog audio signal outputted from the USB-audio signal converter interface 7 is not processed through the audio power amplifier, and is directly outputted through the speakers 3. As a result, the sound signal outputted from the speakers has a lower power suitable for a regular headphone mode of use.

FIG. 2B is a schematic diagram illustrating an operation of the electrical circuit structure according to another embodiment of the present invention. The USB connector plug 11, USB-audio signal converter interface 7, switch 8, audio power amplifier 6 and speakers 3 may be respectively connected in series. In this configuration, the switch 8 is used as an attenuator, such as a progressive rotary switch using an adjustable resistor. The digital audio signal produced by the audio output equipment (which must have a USB interface with audio output capabilities) is transmitted through the USB connector plug 11 to the USB-audio signal converter interface 7. The DAC inside the USB-audio signal converter interface 7 then converts the digital audio signal into an analog audio signal. By adjustment of the attenuator, the analog audio signal can be transmitted at different magnitudes to the audio power amplifier 6. The audio power amplifier then may also be able to output the audio signal at different magnitudes to the speakers 3. In a regular headphone mode of operation, the audio power amplifier is configured with an output magnitude equal to 1 and the attenuator is used as an adjuster, such that the output magnitude may be reduced or increased as a volume control of the headphones. On the other hand, when the attenuator is adjusted so that the output magnitude of the audio power amplifier is gradually increased to a given magnitude value, the audio signal may be heard from the speakers without the need of wearing the headphones. A sound box mode of operation can thereby be achieved, in which an increase of the output magnitude can be used as a volume control of the sound box mode. In addition, the switch 8 can be configured as an adjustable resistor operable to adjust different output magnitudes for the audio power amplifier 6 and USB-audio signal converter interface 7. The BASS output connector 9 is adapted for connecting with an external BASS output source.

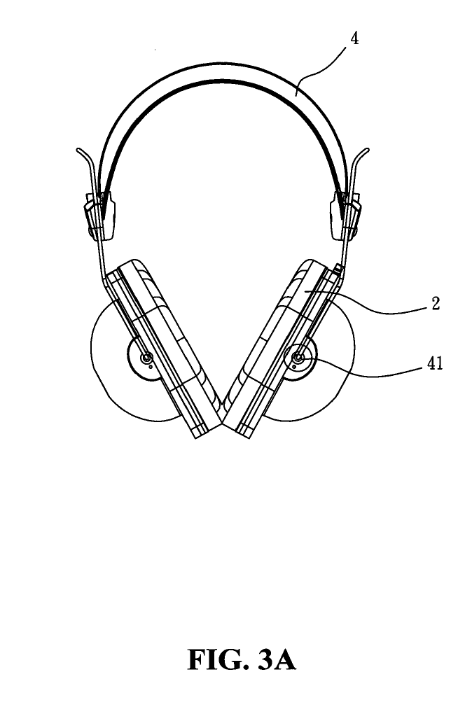

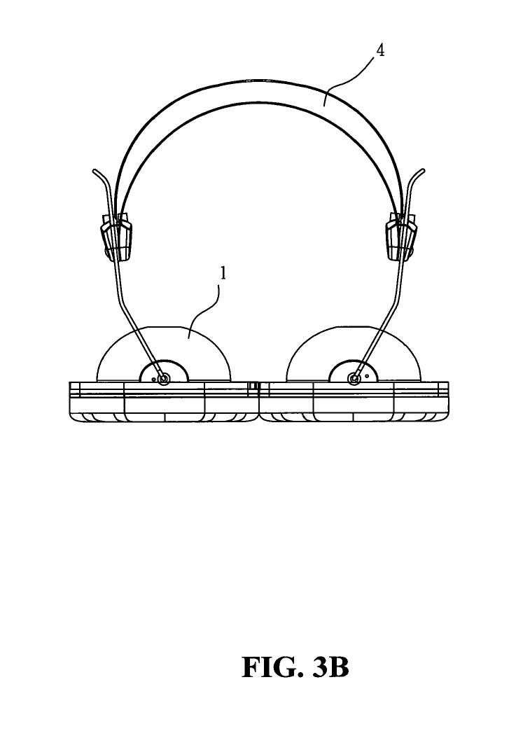

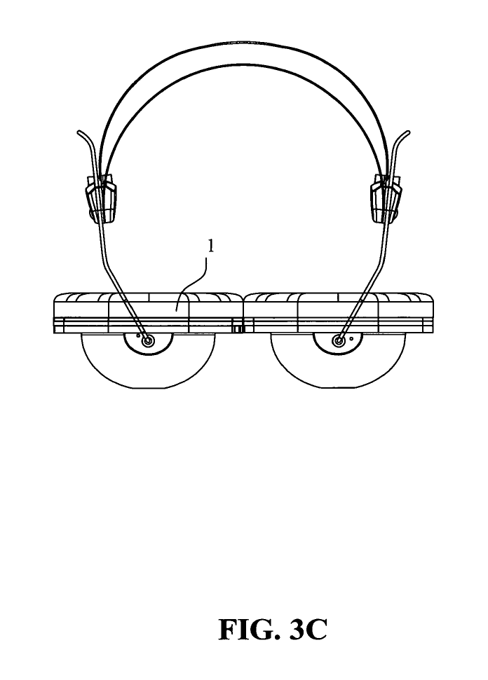

As shown in FIGS. 3A, 3B and 3C, the link between each of the two ear shells 2 and the head band 4 may be a rotary link. In a regular headphone mode of operation, the ear shells 2 may be rotated to a position relative to the head band 4 as shown in FIG. 3A. In a sound box mode, the ear shells 2 may be rotated to another position relative to the head band 4 as shown in FIGS. 3B and 3C. To enable automatic switching between the regular headphone mode and sound box mode, the switch may be also constructed on the ear shells so that it operates in conjunction with the movement of the links between the ear shells and head band. When the ear shells are moved to the position shown in FIG. 3A, the switch is triggered by the link between the ear shell and the head band to turn the electrical circuit to the regular headphone mode of operation. When the ear shells are moved the position shown in FIG. 3B or 3C, the switch is triggered by the same link to turn the electrical circuit to the sound box mode of operation. Such switch mechanism may be designed according to well-known structures, the details of which are omitted herein for the sake of clarity.

It will be worth noting that the components assembled in the enclosing case may be alternatively mounted any of the ear shells. Furthermore, either the enclosing case or one of the ear shells may include an additional socket for accommodating a RCA audio input interface. When an audio output connector of an external audio signal source is connected with the RCA audio input interface, the connection of all the audio outputs with the USB-audio converter interface is switched to the RCA audio input interface. To enable higher power of the audio output in the sound box mode of operation, the enclosing case may also include an extra socket for accommodating a power supply input interface adapted to be coupled with an external power supply. External power may thus be supplied to the audio power amplifier to increase the power of its audio output.

### Embodiment 2

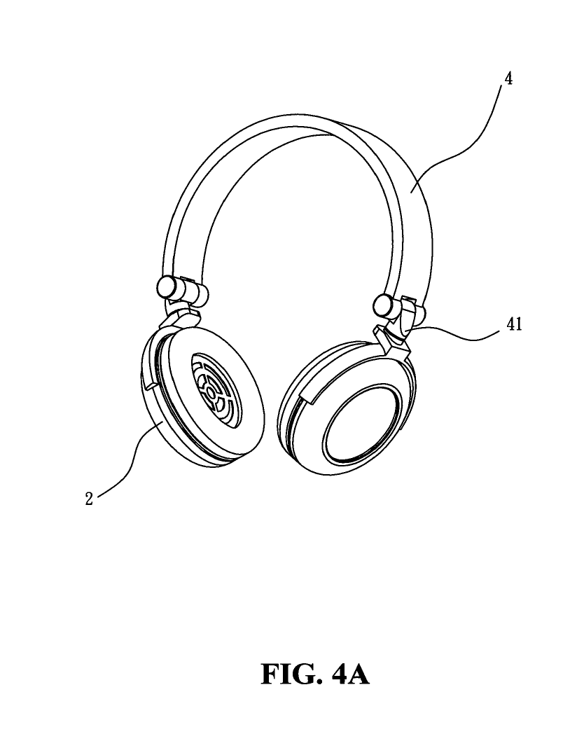

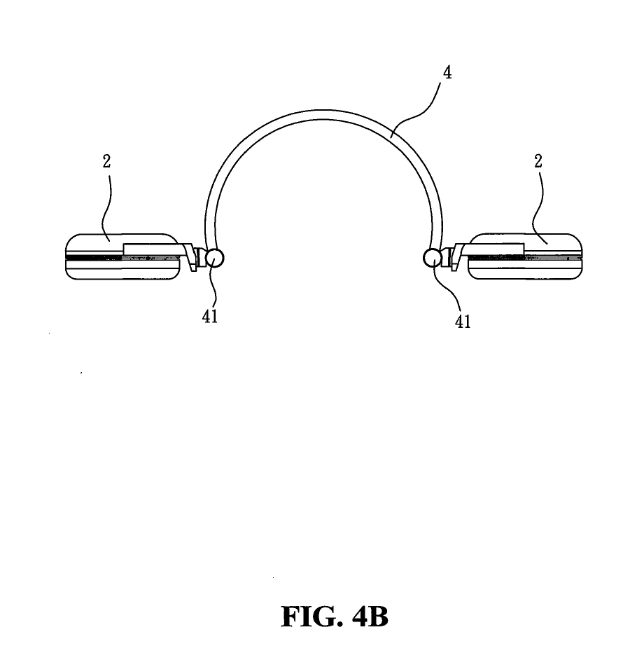

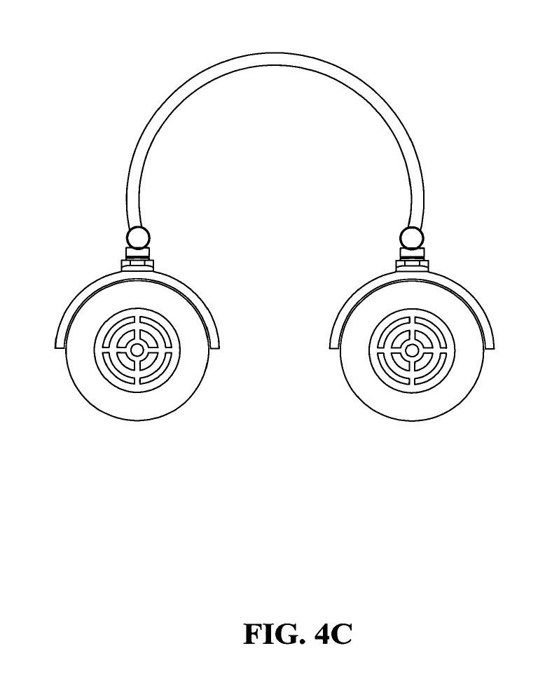

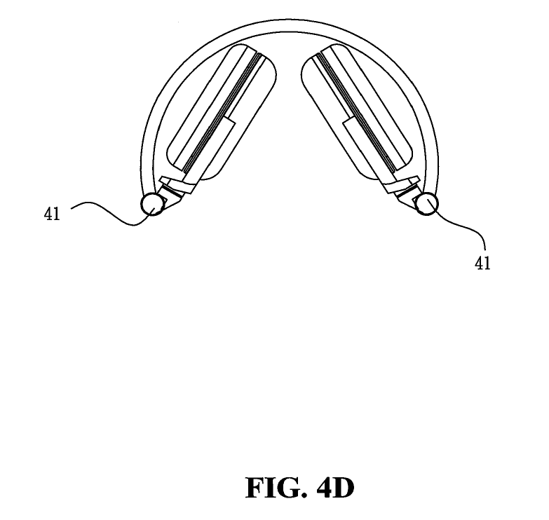

As shown in FIGS. 4A, 4B, 4C and 4D, the embodiment 2 differs from the embodiment 1 in that the link 41 between each ear shell 2 and the head band 4 is a cylindrical joint assembly. Accordingly, each ear shell is able to perform 2-dimensional and 3-dimensional rotations relative to the head band to satisfy different configurations of use and allow convenient arrangement in a reduced volume when it is not used, thereby facilitating its portability.

In other embodiments, the link structure may also include a combination of cylindrical and spherical joint assembly as well-known in the art.

### Embodiment 3

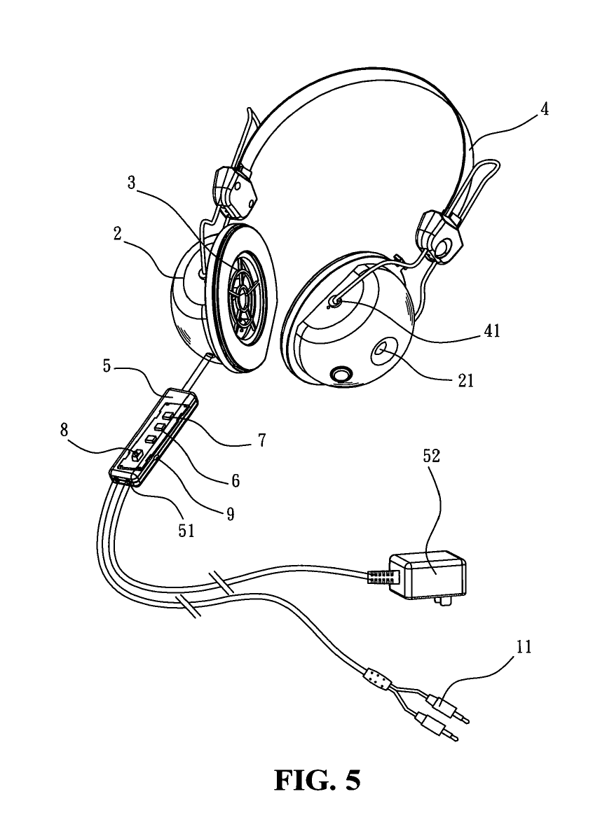

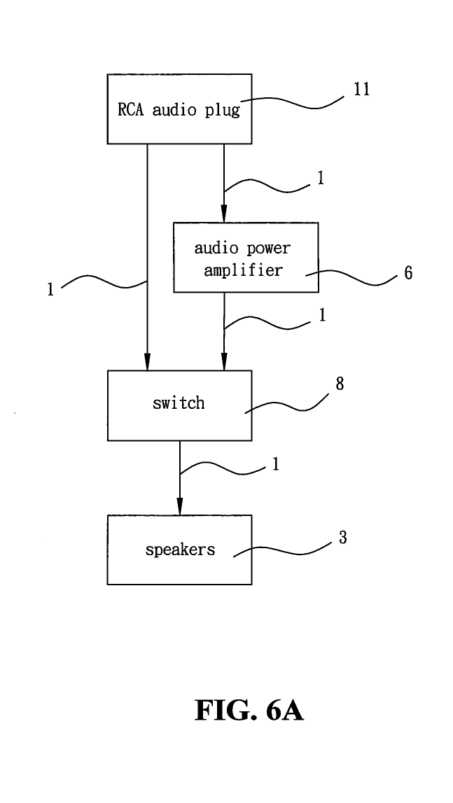

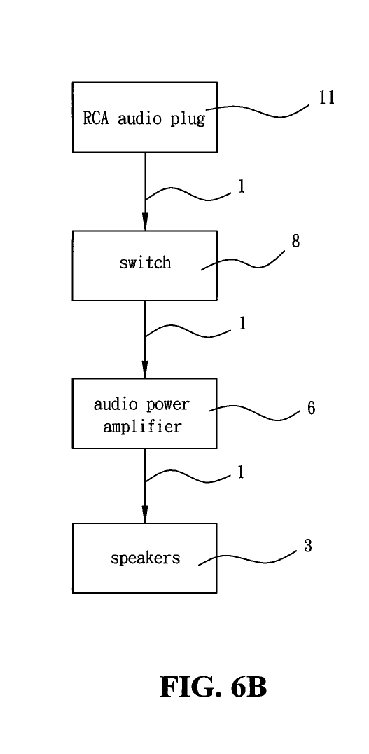

As shown in FIG. 5, the headphones according to the embodiment 3 mainly comprise a head band 4, two ear shells 2, and a conductor cord 1 provided with a connector plug 11. Each ear shell 2 is respectively connected with an end of the head band 4 through a link 41, and comprises a speaker 3 mounted therein. The cord 1 is electrically connected with each speaker 3. The connector plug 11 is a RCA audio plug. A portion of the cord 1 is also provided with an enclosing case 5 in which are respectfully assembled a switch 8, a BASS output connector 9, and an audio power amplifier 6. The RCA connector plug, switch 8, audio power amplifier 6 and speakers 3 constitute the main circuitry of the present embodiment 3. The switching mechanism of the electrical circuit between the sound box and regular headphone modes of operation are described below in conjunction with the schematic diagrams of FIGS. 6A and 6B.

FIG. 6A is a schematic diagram illustrating an operation of the embodiment 3. When the switch 8 (the switch may be either a push button or sliding tab switch) is turned to a sound box mode of operation, the analog audio signal produced by an audio output equipment is transmitted through the RCA audio plug and audio power amplifier 6 to the switch 8. After amplification through the audio power amplifier, the analog audio signal is outputted through the speakers 3 with an increased power and volume such as from a sound box. On the other hand, when the switch is turned to the regular headphone mode of operation, the analog audio signal produced by the audio output equipment is transmitted through the RCA audio plug and the switch, and then is directly outputted through the speakers. As a result, the audio signal outputted from the speakers has a lower power and volume suitable for a regular headphone mode of operation.

FIG. 6B is a schematic diagram illustrating an operation of the electrical circuitry of the headphones according to another embodiment of the present invention. The RCA audio plug 11, switch 8, audio power amplifier 6 and speakers 3 are respectively connected in series to form the electrical circuitry of the headphone set. In this configuration, the switch 8 is used as an attenuator, such as a progressive rotary switch using an adjustable resistor. The analog audio signal produced by the audio output equipment is transmitted through the RCA audio plug and attenuator. By adjustment of the attenuator, the analog audio signal can be transmitted at different magnitudes to the audio power amplifier. In a regular headphone mode of operation, the audio power amplifier is configured with an output magnitude equal to 1 and the attenuator is used as an adjuster, such that the output magnitude may be reduced or increased as a volume control of the headphones. On the other hand, when the attenuator is adjusted so that the output magnitude of the audio power amplifier is gradually increased to a given magnitude value, the audio signal may be heard from the speakers without the need of wearing the headphones. A sound box mode of operation can thereby be achieved, in which an increase of the output magnitude can be used as a volume control of the sound box mode. In addition, the switch 8 can be configured as an adjustable resistor operable to adjust different output magnitudes of the audio power amplifier 6.

To enable higher audio output power in the sound box mode, the enclosing case may include an additional socket 51 for accommodating a power input interface. An external power source adapter 52 may be connected with the socket 51, thereby power may be supplied to the audio power amplifier to increase output power thereof. The external power source adapter 52 may be replaced with a USB connector plug.

Variations of the above embodiments may be similar to those of the embodiment 1.

### Embodiment 4

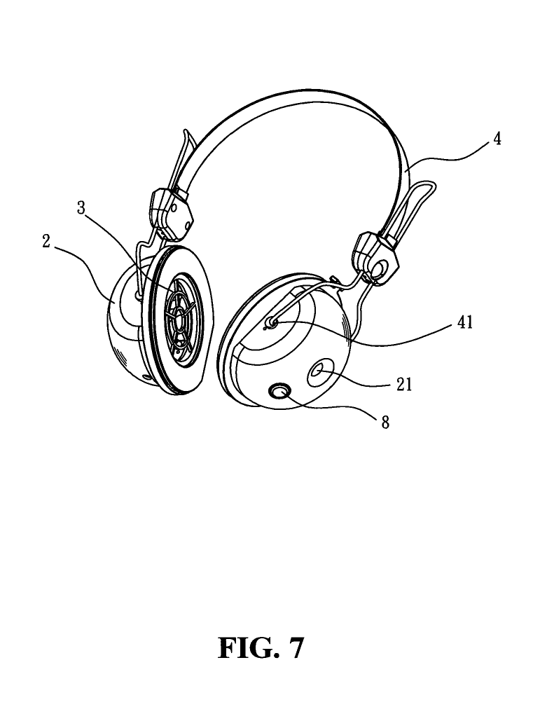

As shown FIG. 7, the embodiment 4 differs from the embodiment 1 in that the switch 8 is a push button switch that is mounted on one of the ear shell 2. The electrical circuitry and switching mechanism may be similar to the embodiments described above in conjunction with FIGS. 2A and 6A.

### Embodiment 5

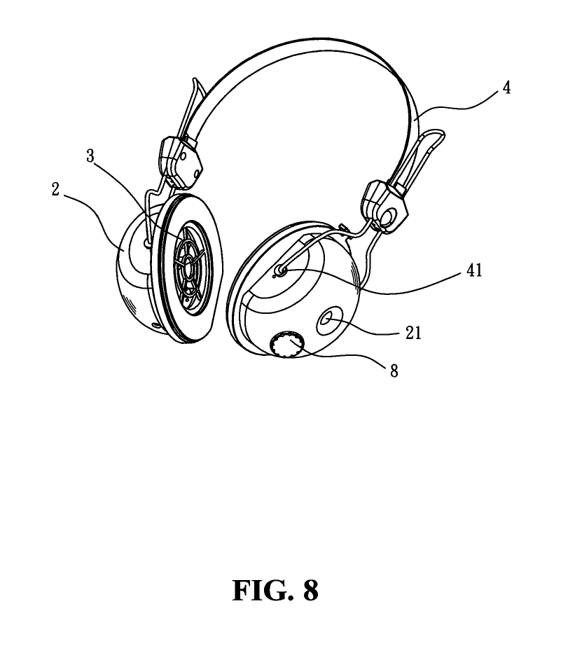

As shown in FIG. 8, the embodiment 5 differs from the embodiment 1 in that the switch 8 is a rotary switch that is adapted to be used as volume control and is mounted on one of the two ear shells 2. The electrical circuitry and switching mechanism may be similar to the embodiments described above in conjunction with FIGS. 2B and 6B.

In variant embodiments, depending on the structure of the links between the head band and the two ear shells as well as the switch mechanism, the head band may also be designed as a foldable or detachable head band. In other words, a portion of the head band, preferably its central region, is provided with a folding or detachment structure that divides the head band into two halves movable relative to each other. The relative movement between the two halves of the head band results in a relative movement between the two ear shells to comply with either a headphones or sound box mode of use. Moreover, the folding or detachment structure may also be coupled with the switch to enable automatic switching between the headphones and sound box mode of operation.

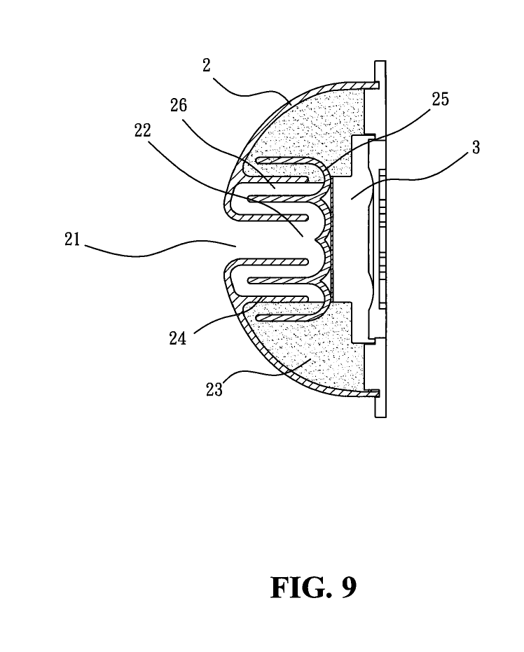

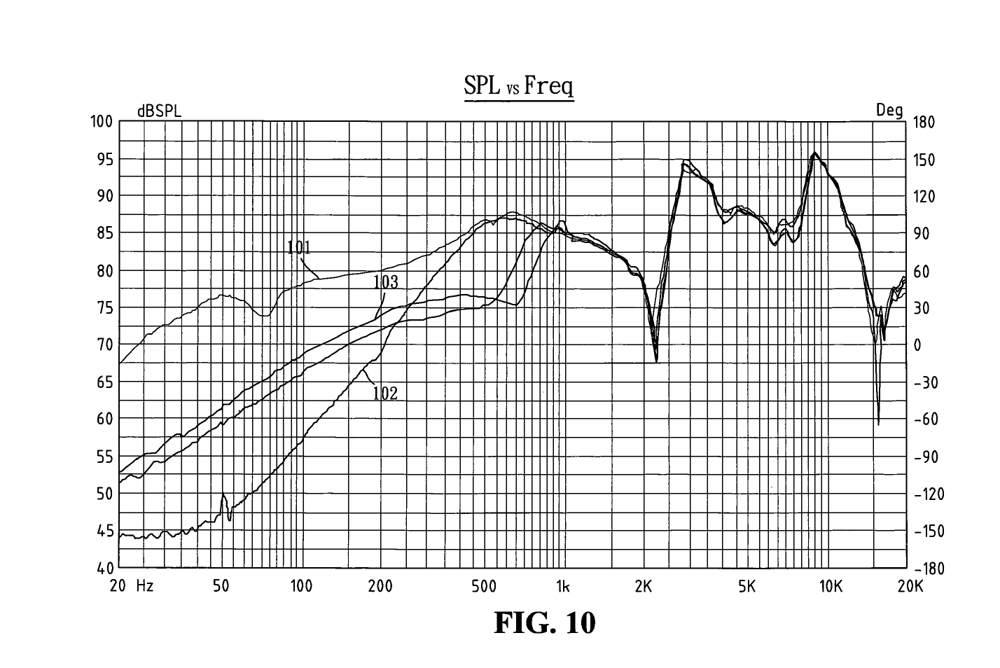

As shown in FIG. 9, an inner chamber of each ear shell 2 is configured with a transmission line of Helmholtz resonance. A vent aperture 21 at one end of the transmission line is located on an outer case of the ear shell 2, which is an open hole on a rear wall of the outer case of the ear shell 2. An inner surface of the outer case preferably defines a curved shape. The speaker 3 is located on a front end of the outer case of the ear shell 2. The outer case and the speaker 3 define a chamber 22 that has a relatively larger accommodating space. A rear interior of each ear shell has a concentric annular ring 24 with a center on a central axis of the vent aperture 21. The vent aperture 21 and the concentric annular ring 24 may be located on a same axis as the speaker 3. A concentric annular lid 25 covers on the concentric annular ring 24, thereby forming an annular U-shaped or V-shaped roundabout channel 26. The vent aperture 21 defines an opening of the channel 26. The chamber 22 communicates through the annular channel 26 with the vent aperture 21 on the rear end of the outer case, thereby constituting the transmission line of Helmholtz resonance adapted to emphasize in an effective manner bass frequency outputs of each of the headphones in the sound box mode. A cross-section of the transmission line appears as multiple concentric rings with a center on the central axis of the vent aperture 21, such as concentric circles or ellipses. One of the concentric rings or the outmost ring of the transmission line has a size that is approximately equal to a periphery of the permanent magnetic body of the speaker. A greatest resonance peak for bass frequencies can thereby be obtained for emphasizing bass frequency outputs of the headphones in the sound box. FIG. 10 is a graph comparing certain characteristics of an embodiment of the present invention with a conventional headphone device. Reference number 103 designates a curve representative of a sound pressure output of an ear shell including the speaker, reference number 102 designates a curve representative of a sound pressure output from the open hole on the ear shell, and reference number 101 designates a curve representative of an ear shell including a speaker and having an inner chamber configured with a transmission line of Helmholtz resonance according to the present invention. As shown, the headphones according to the present invention have amplified bass outputs and smaller standing waves, which yields enhanced sound quality. In addition, as the concentric annular lid 25 is located between the vent aperture 21 and the speaker 3, the concentric annular lid and the speaker can be easily mounted and fixed, so as to facilitate its mass production. Moreover, the inner chamber of each ear shell may also be filled with a sound-absorbing material 23 to provide enhanced sound quality.

### Embodiment 6

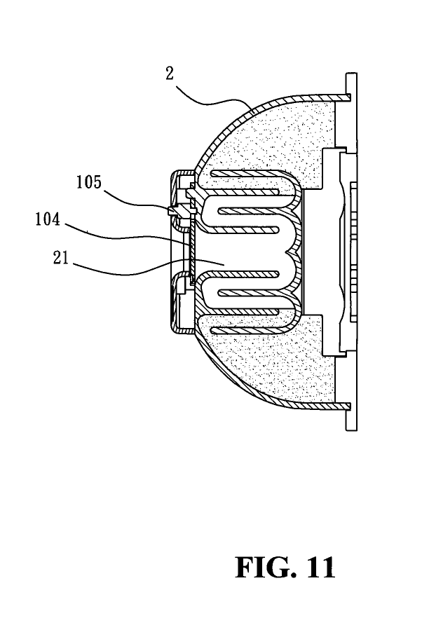

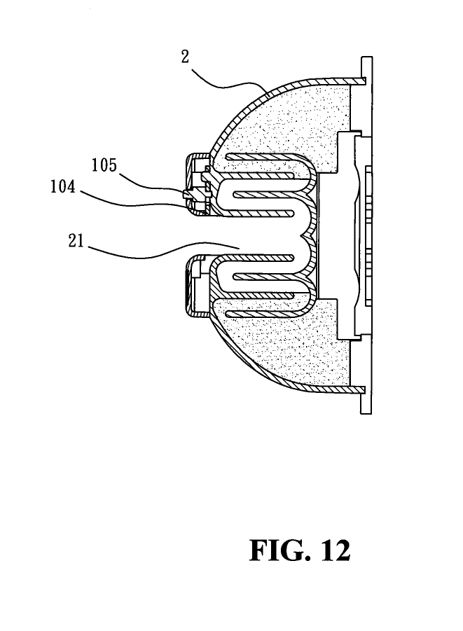

FIG. 11 is a schematic view illustrating another embodiment of the present invention. An occluding member 104 may be provided for adjusting the size of the vent aperture 21. The occluding member 104 may be connected with an operating member 105 through which the occluding member 104 may be moved and adjusted to close (as shown in FIG. 11), or open (as shown in FIG. 12) the vent aperture 21. When the embodiment of the present invention is in a headphone mode of operation, a user can manipulate the operating member 105 and the occluding member 104 to adjust the size of the vent aperture 21 or even close the vent aperture 21, thereby preventing excessively high bass sound outputs that may render the listening experience uncomfortable. When in the sound box mode of operation, the occluding member 104 may be operated to open or increase the size of the vent aperture 21. The transmission element between the operating member 105 and the occluding member 104 may include a gear assembly or linkage mechanism, which may be electrically or manually controlled.

The foregoing description is intended to only provide illustrative ways of implementing the present invention, and should not be construed as limitations to the scope of the present invention. A person skilled in the art will readily appreciate that various modifications may be applied to diverse parts, such as the structure of the switch, the mechanism for implementing automatic switching between the different modes of operation, or the electrical circuit implementation. While the foregoing is directed to embodiments of the present invention, other and further embodiments of the invention may thus be devised without departing from the basic scope thereof, and the scope thereof is determined by the claims that follow.

What is claimed is:

1. A set of headphones switchable to a sound box mode of operation, comprising:
two ear shells, wherein each ear shell is internally provided with a speaker and has an inner chamber configured with a transmission line of Helmholtz resonance, a vent aperture at one end of the transmission line is located on an outer case of the ear shell for emphasizing bass outputs;
a cord, having a connector plug, wherein the cord is connected with the speakers, and a portion of the cord is provided with an audio power amplifier connected between the connector plug and the speakers; and
a switch, operably switching an audio signal outputted through the speakers between different levels of power and thereby switching between a headphone mode and a sound box mode of operation.

2. The headphones according to claim 1, wherein the connector plug is an USB plug, and the cord is further provided with a USB-audio signal converter interface coupled between the USB plug and the audio power amplifier.

3. The headphones according to claim 2, wherein the switch is operable to switch connection between the speakers and an output of the audio power amplifier when the speakers are directly connected with an output of the USB-audio signal converter interface.

4. The headphones according to claim 1, wherein the switch is configured to enable and disable the audio power amplifier.

5. The headphones according to claim 1, wherein the switch is a mechanically sliding switch, a push button switch, or a rotary switch operable to adjust a sound volume.

6. The headphones according to claim 1, wherein the switch is an attenuator coupled between the connector plug and the audio power amplifier.

7. The headphones according to claim 1, further comprising an enclosing case housing the audio power amplifier.

8. The headphones according to claim 1, further comprising an enclosing case housing the audio power amplifier and the USB-audio signal converter interface.

9. The headphones according to claim 7 or 8, wherein the switch is mounted in the enclosing case.

10. The headphones according to claim 7 or 8, wherein the enclosing case includes a socket adapted to connect with an external power source adapter for supplying power to the audio power amplifier.

11. The headphones according to claim 7 or 8, wherein the enclosing case includes a socket adapted connect with an external audio signal source for providing an audio signal to the audio power amplifier.

12. The headphones according to claim 7 or 8, wherein the enclosing case includes a bass output connector adapted for connecting with an external BASS output source.

13. The headphones according to claim 10, wherein the external power source adapter is a USB connector plug.

14. The headphones according to claim 2, wherein the audio power amplifier and the USB-audio signal converter interface are provided in any one of the two ear shells.

15. The headphones according to claim 1, wherein the switch is a push button or a rotary switch adapted for volume control provided on an outer surface of any one of the ear shells.

16. The headphones according to claim 1, further comprising a head band having two ends respectively connected with the ear shells.

17. The headphones according to claim 16, wherein each ear shell is connected with the head band through a rotary link structure.

18. The headphones according to claim 16, wherein each ear shell is connected with the head band through a detachable link structure.

19. The headphones according to claim 17 or 18, wherein the switch is operatively triggered by the link structure between the head band and the ear shells.

20. The headphones according to claim 16, wherein the head band is a foldable or detachable head band.

21. The headphones according to claim 20, wherein the switch is operatively triggered by the foldable or detachable head band.

22. The headphones according to claim 1, wherein the transmission line has concentric rings with a center on a central axis of the vent aperture.

23. The headphones according to claim 22, wherein an outmost ring of the concentric rings of the transmission line has a size approximately equal to a periphery of a permanent magnetic body of the speakers.

24. The headphones according to claim 1, wherein an inner chamber of each ear shell has a sound absorbing material.

25. A set of headphones switchable to a sound box mode of operation, comprising:
two ear shells, wherein each ear shell is internally provided with a speaker and has an inner chamber configured with a transmission line of Helmholtz resonance, a vent aperture at one end of the transmission line is located on an outer case of the ear shell for emphasizing bass outputs;
an enclosing case including a cord having a connector plug, wherein the cord is connected with the speakers, the enclosing case further including an audio power amplifier, a bass output connector, and a switch operably switching an audio signal outputted through the speakers between different levels of power and thereby switching between a headphone mode and a sound box mode of operation; and
a bass speaker device including a second cord having a second connector plug, wherein the second connector plug is adapted to connect with the bass output connector of the enclosing case.

26. The headphones according to claim 25, wherein the connector plug is a RAC connector or a USB connector.

27. The headphones according to claim 25, wherein the transmission line has concentric rings with a center on a central axis of the vent aperture.

28. The headphones according to claim 25, further comprising a head band having two ends respectively connected with the ear shells.

29. A set of headphones switchable to a sound box mode of operation, wherein the headphones include two ear shells each having a speaker and an outer case, the outer case comprising:
a vent aperture disposed on a rear side of the outer case;
a plurality of concentric rings defined in an interior of the outer case, wherein the concentric rings has a center on a central axis of the vent aperture;
an opening defined on a front end of the outer case, which has a larger accommodating space at the front end thereof, the speaker being disposed in the opening to define a sound box chamber;
a concentric annular lid, placed between the speaker and the outer case and covering the vent aperture and the concentric rings, thereby defining a transmission line of Helmholtz resonance that communicates the chamber to the vent aperture for emphasizing bass outputs.

30. The headphones according to claim 29, wherein the transmission line communicating the chamber to the vent aperture includes at least a U- or V-shaped channel.

31. The headphones according to claim 29, wherein an outmost ring of the concentric rings of the transmission line has a size approximately equal to a periphery of a permanent magnetic body of the speaker.

32. The headphones according to claim 29, wherein the concentric annular lid is placed between the speaker and the vent aperture of the outer case.

33. The headphones according to claim 29, wherein the headphones is a head-mounted headphone.

34. The headphones according to claim 29, further comprising a cord having a connector plug, wherein the cord is connected with each speaker and includes an audio power amplifier coupled between the connector plug and the speakers; and a switch operably switching an audio signal outputted through the speakers between different levels of power.

35. A set of headphones switchable to a sound box mode of operation, wherein the headphones include two ear shells each having a speaker and an outer case, the outer case defines an accommodating space, the accommodating space is configured with a transmission line of Helmholtz resonance, and a vent aperture at one end of the transmission line is located a rear end of the outer case of each ear shell for emphasizing bass outputs.

36. The headphones according to claim 35, further comprising a concentric annular lid placed between the speaker and the outer case of each ear shell and covering the vent aperture, wherein the transmission line of Helmholtz resonance communicates the accommodating space to the vent aperture for emphasizing bass outputs.

37. The headphones according to claim 35, wherein the transmission line communicating the accommodating space to the vent aperture includes at least a U- or V-shaped channel.

38. The headphones according to any one of claim 1, 25, 29 or 35, wherein the vent aperture of the transmission line and the speaker are located on a same axis.

39. The headphones according to any one of claim 1, 25, 29 or 35, wherein an inner surface of one outer case is a curved shape.

40. The headphones according to any one of claim 1, 25, 29 or 35, wherein a rear end of the outer case is provided with an occluding member movable to close or open the vent aperture.

41. The headphones according to claim 40, wherein the occluding member is connected with an operating member that is operable to control a movement of the occluding member relative to the vent aperture for adjusting, closing or opening the vent aperture.
